(19) United States
(12) Patent Application Publication
(10) Pub. No.: US 2010/0117059 A1
(43) Pub. Date: May 13, 2010

(54) LIGHT MODULATION COMPRISING SI-GE QUANTUM WELL LAYERS

(75) Inventors: Daniel Chrastina, Como (IT); Hans-Christen Sigg, Mettmenstetten (CH); Soichiro Tsujino, Brugg (CH); Hans Von Känel, Wallisellen (CH)

Correspondence Address: LERNER GREENBERG STEMER LLP, P O BOX 2480, HOLLYWOOD, FL, 33022-2480, US

(73) Assignees: PAUL SCHERRER INSTITUT, Villigen (CH); POLITECNICO DI MILANO, Milano (IT)

(21) Appl. No.: 12/377,128

(22) PCT Filed: Aug. 7, 2007
(86) PCT No.: PCT/EP2007/006974

§ 371 Date: Mar. 25, 2009

(30) Foreign Application Priority Data
Aug. 11, 2006 (EP) 06016771.5

(51) Int. Cl. H01L 29/15

(52) U.S. Cl. 257/19; 257/E29.073; 977/760

(57) ABSTRACT

Optical modulators include active quantum well structures coherent with pseudosubstrates comprising relaxed buffer layers on a silicon substrate. In a preferred method the active structures, consisting of Si₁₋ₓ Geₓ barrier and well layers with different Ge contents x, are chosen in order to be strain compensated. The Ge content in the active structures may vary in a step-wise fashion along the growth direction or in the form of parabolas within the quantum well regions. Optical modulation may be achieved by a plurality of physical effects, such as the Quantum Confined or Optical Stark Effect, the Franz-Keldysh Effect, exciton quenching by hole injection, phase space filling, or temperature modulation. In a preferred method the modulator structures are grown epitaxially by low-energy plasma-enhanced chemical vapor deposition (LEPCVD).

The invention relates to light modulation in Si—Ge quantum well layers at wavelengths suitable for fiberoptics- communications.

While the role of silicon as the major material for electronics is well known, its application to optoelectronics and photonics has been less evident. The reason for this shortcoming lies in the nature of its electronic band structure, especially its indirect energy gap, as a result of which it exhibits inferior optoelectronic properties in comparison with many compound semiconductors, such as for example GaAs, InP and their alloys from which semiconductor lasers, detectors and modulators are usually made.

The indirect energy gap of Si has so far precluded its use as a laser material, with the exception of the recently demonstrated Raman laser, requiring optical pumping. Silicon's applications to detectors and modulators for optical communications purposes are hindered less by the nature of its gap but rather by its size, making it impossible to absorb light at the relevant wavelengths of 1.3 and 1.55 μm. In order to make Si suitable for such applications it therefore needs to be combined with other materials. While monolithic integration of compound semiconductor optoelectronic and silicon electronic functionalities would be the most desirable form of this combination, this approach has so far been hampered by materials compatibility issues (for a review on GaAs integration, see for example Mat. Res. Soc. Symp. Proc. 116 (1989), the content of which is incorporated herein by reference).

Germanium on the other hand is a material largely compatible with Si processing, and therefore much easier to incorporate into a Si technology, as shown for example in U.S. Pat. No. 5,006,912 to Smith et al., the content of which is incorporated herein by reference. Integrated SiGe/Si optoelectronic integrated circuits have in fact been proposed (see for example U.S. Pat. No. 6,784,466 to Chu et al., the content of which is incorporated herein by reference).

The application of SiGe/Si heterostructures to optoelectronic devices integrated on Si substrates is facilitated by the favorable band structure of Ge with a direct transition at the Γ-point with an energy of 0.8 eV, not far above the indirect fundamental gap of 0.66 eV. This, together with the miscibility of Si and Ge over the whole concentration range, has led to a number of proposals for device applications. Photodetectors made from epitaxial Ge layers on Si substrates have been proposed for example by Wada et al., in U.S. Pat. No. 6,812,495, the content of which is incorporated herein by reference. Optical modulators based on the Franz-Keldysh effect, in which the absorption edge is shifted in the presence of an electric field, have been proposed by Kimerling et al., in U.S. Pat. No. 2003/0138178, the content of which is incorporated herein by reference. Other concepts make use of the quantum-confined Stark Effect in SiGe quantum wells (see for example U.S. Pat. No. 2006/0124919 to Harris et al., the content of which is incorporated herein by reference).

It is a common feature of all prior art that optoelectronic devices have been fabricated from material epitaxially deposited by either molecular beam epitaxy (MBE) or chemical vapour deposition (CVD). It is a further common feature that optoelectronic SiGe devices suitable for operation at wavelengths of 1.3 and 1.55 μm need to be composed of Ge-rich layers, since the energies of indirect and direct band gaps rise rapidly with decreasing Ge-content in SiGe alloys. For example the energy of the direct gap at the Γ-point of a Si₁₋ₓGeₓ alloy corresponds to a wavelength of 1.3 μm at a Ge-content of approximately x=0.95. At lower Ge-contents light with a wavelength of 1.3 μm can no longer induce a direct transition, and is therefore not efficiently absorbed. As a result, detectors and modulators made of Si-rich material require light to travel long distances or may no longer be applicable to wavelengths of 1.3 and 1.55 μm at all.

Unfortunately, the high Ge-contents necessary for optoelectronic devices of the kind considered above makes their fabrication by MBE or CVD cumbersome. The reason is that low growth temperatures need to be used in order to control the epitaxial growth, where especially CVD, considered to be the main production technique, becomes inherently slow (see for example see for example U.S. Pat. No. 5,659,187 to Legoues et al. and Yu-Hsuan Kuo et al., Nature 437 (2005) pp. 1334-1336, the contents of which are incorporated herein by reference).

A prior art technique providing fast epitaxial growth at low substrate temperatures is low-energy plasma-enhanced chemical vapour deposition (LEPECVD), which previously was applied to the fabrication of electronic SiGe material (see for example Int. Pat. Nos. WO 03/044839A2 to von Känel, and WO2004085717A1, the contents of which are incorporated herein by reference).

It is therefore an objective of the present invention to provide an optical modulation structure offering a sufficient optical band gap for light modulation in fiberoptics communication and being manufactured efficiently.

The present invention comprises optical modulators in compressively strained Si₁₋₁Geₓ quantum wells with Ge-contents x chosen in a range such that the direct Γ_{25′}-Γ_{2′} transition, also denoted as Γ₈⁺-Γ₇⁻ transition in the double-group representation, lies below the Γ_{25′}-Γ₁₅ transition. Modulation is based on a plurality of physical effects, such as the quantum-confined Stark effect (QCSE), exciton quenching or band filling by hole injection, the Franz-Keldysh effect, or thermal modulation of the band structure, or thermal modulation of the index of refraction and absorption coefficient via modulation of the carrier temperature. A preferred method of providing such structures is by growing single or multiple quantum wells onto relaxed SiGe buffer layers by low-energy plasma-enhanced chemical vapour deposition (LEPECVD).

According to one aspect of the present invention LEPECVD provides a method for growing strain-compensated Si_{1-y}Ge_{y}/Si₁₋ₓGeₓ/Si_{1-y′}Ge_{y′} quantum wells onto relaxed SiGe buffer layers acting as pseudosubstrates, where x>y, y′, and y and y′ may vary along the growth direction, preferably y and y′ may increase along the growth direction.

According to another aspect of the present invention LEPECVD provides a method for fabricating single or multiple quantum well structures incorporating doped layers underneath the active layers.

### BRIEF DESCRIPTION OF THE DRAWINGS

FIG. 1 shows the band structures of pure Si and Ge;

FIG. 2 shows a multiple quantum well structure;

FIG. 3 shows two possible profiles of the Ge content in the active layer structure;

FIG. 4 is a reciprocal space map of a Ge/SiGe multiple quantum well structure on a relaxed graded SiGe alloy layer;

FIG. 5 shows reciprocal space maps of pseudosubstrates comprising a constant-composition SiGe alloy layer;

FIG. 6 shows a modulator structure with Schottky contact on the top;

FIG. 7 shows absorption spectra of a Ge/SiGe multiple quantum well (MQW) structure grown on relaxed graded SiGe alloy layer;

FIG. 8 shows absorption spectra of a Ge/SiGe MQW device for various applied voltages; and

FIG. 9 shows a modulator structure with an integrated heater element.

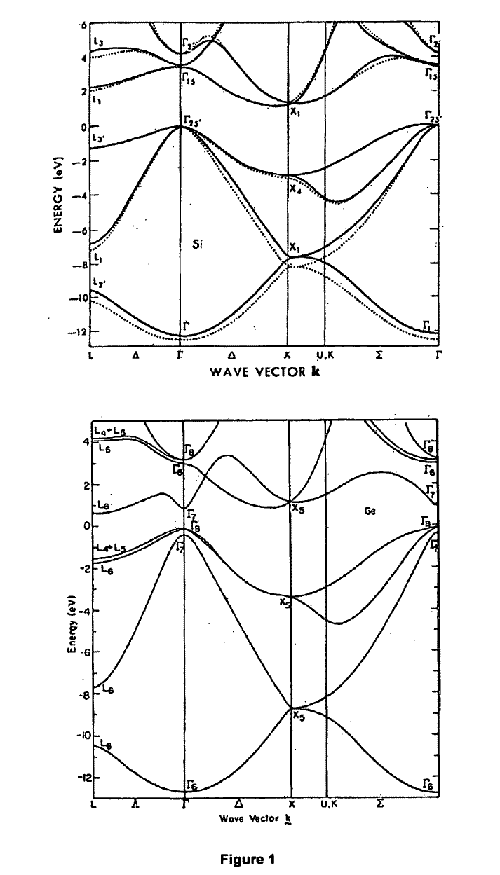

The invention can best be appreciated by noting that upon alloying Si and Ge the lowest energy direct transition at the Γ-point occurs from the valence band Γ_{25′} to the σ_{2′} conduction band (see FIG. 1), except for Ge contents below about 30%. For any optoelectronic material of interest for fiberoptic communications (λ=1.3 or 1.5 μm) the interest of the present invention to active Si₁₋ₓGeₓ layers ranges with Ge contents above about x=0.3.

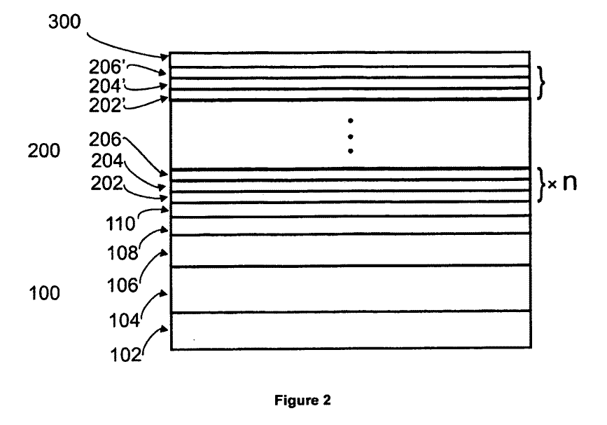

In one embodiment of the invention shown in FIG. 2 an active single or multiple quantum well structure 200, consisting of n well layers 204, 204′ and Si_{1-y}Ge_{y} barrier layers 202, 206; 202′, 206′, with x>y is grown onto a strain relaxed SiGe buffer layer 100 acting as a pseudosubstrate. Preferably, the average Ge content of the active quantum well structure 200 is chosen to be close to or equal to the Ge content x_{f} at the top of the buffer layer, such as to provide partial or complete strain compensation. The barrier layers 202, 206; 202′, 206′ and well layers 204, 204′ may be doped or undoped. The pseudosubstrate 100 may be comprised of a Si substrate 102, a doped or undoped Si_{1-x′}Ge_{x′} alloy layer 104 with a graded Ge content, whereby x′ can be established in the range of the value for x_{f}. Following layer 104 another doped or undoped layer 106 is grown with a constant final Ge content x_{f}, determining the lattice parameter of the pseudosubstrate. Next a boron-doped layer 108 is grown, followed by an undoped layer 110, both at a Ge content of x_{f}. Following the active layer structure 200 a cap layer 300 is grown, which may be undoped or doped with donor impurities, and which preferably has a composition of Si_{1-xf}Ge_{xf}.

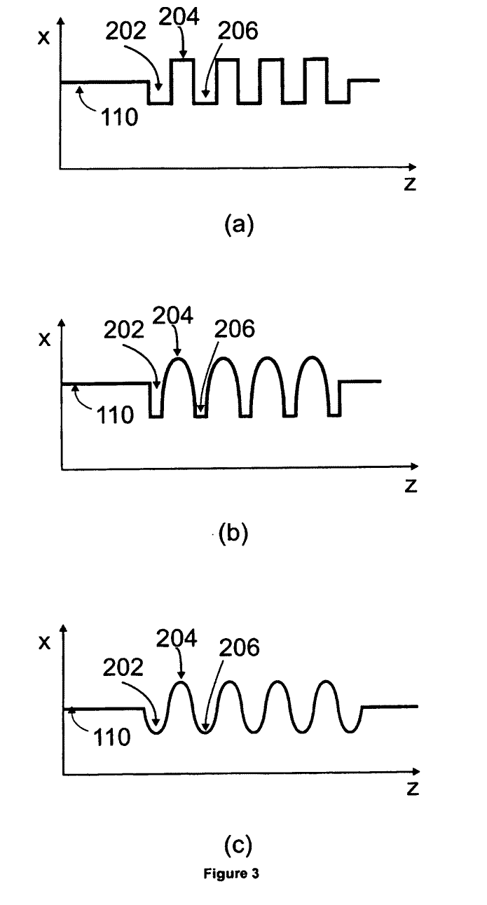

The complete layer sequence 100-300 is preferably grown by LEPECVD, wherein growth time of the pseudosubstrate 100 can be minimized by choosing dense-plasma conditions offering high deposition rates, while active layer structures 200 are deposited at low rates by reducing the plasma density. The actual Ge profile in active layer structures 200 can be chosen to have a plurality of shapes, examples of which are specified in FIG. 3.

In one embodiment of the invention the active layer structure 200 is obtained by changing the Ge content in a step-wise fashion, as shown in FIG. 3(a).

In another embodiment of the invention the Ge profile in the quantum well layer(s) 204 of active layer structure 200 is chosen to have a parabolic shape, as shown in FIG. 3(b).

In yet another embodiment of the invention the Ge profile in the quantum well layer(s), 204 and in the barrier layers 202, 206 of active layer structure 200 is chosen to have a sinusoidal shape, as shown in FIG. 3(c).

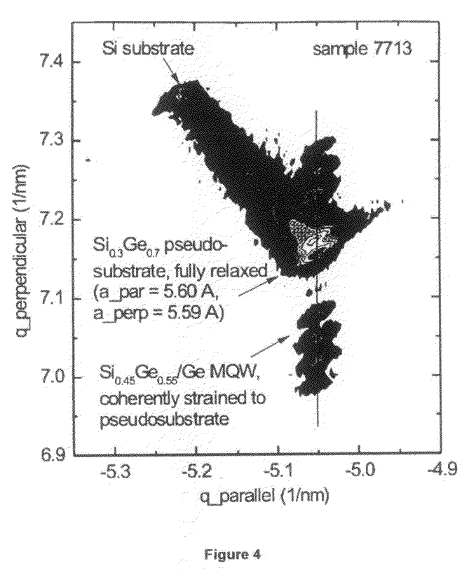

The combination of fast pseudosubstrate growth and slow active layer growth yields active quantum well structures fully strained to the underlying pseudosubstrate, as shown in FIG. 4 for a strain-compensated active layer structure 200 having the step-like Ge profile of FIG. 3(b). FIG. 4 is a X-ray reciprocal space map in the vicinity of an asymmetric <224> reflection, showing that the pseudosubstrate 100 graded to a final Ge content of 70% is fully relaxed, while the active layer structure, comprising tensile-strained Si_{0.45}Ge_{0.55} layers and compressively strained Ge layers, is coherent with the pseudosubstrate. Similar strain compensated quantum well structures have been obtained on pseudosubstrates final Ge contents x_{f} of 80 and 90%.

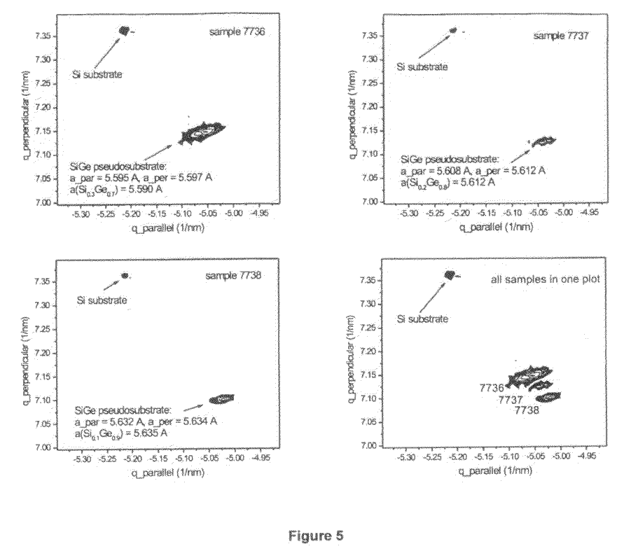

In another embodiment the pseudosubstrate comprises a Si_{1-x′}Ge_{x′} buffer layer with a constant Ge content. This has the advantage of smoother surfaces since the surface cross-hatch normally present on graded buffer layers is absent in this case. According to the present invention Ge-rich Si_{1-x′}Ge_{x′} buffer layers deposited by LEPECVD at constant Ge content x′ are fully strain relaxed, even in the absence of a post-growth anneal. This can be seen in the X-ray reciprocal space map of FIG. 5 for buffer layers with Ge contents of 70, 80 and 90%. The layers were epitaxially grown on Si(001) at a substrate temperature of 520° C. As can be seen from FIG. 5, the mosaic structure of the x′=70% sample is most pronounced, indicating that the crystal quality deteriorates with decreasing Ge content. The quality can, however, be improved by post-growth annealing.

In a preferred embodiment of the invention, a boron doped layer 108 followed by an undoped spacer layer 110 is grown before the active layer structure 200. According to the invention boron segregation into the active layer structure 200 can be prevented by employing the following means. First the substrate temperature is decreased to at least 550° C. during growth of buffer layers 104 and 106. In a second step, the plasma density is lowered by about a factor of about ten before the boron doped layer 108. This has been shown to be effective in preventing dopant segregation induced by ion bombardment. In a third step the boron doped layer 108 is grown at reduced plasma density, and preferably reduced temperature to below 520° C., by introducing a diborane containing gas to the deposition chamber. Boron segregation can further be minimized by admixing a flux of hydrogen gas during growth of doped layer 108 and subsequent undoped layer 110, whereby the hydrogen flux is preferably chosen to be larger than the flux of the doping gas. For example for the structure of FIG. 4 the hydrogen flux was twice as large as the flux provided by the mass flow controller introducing the doping gas.

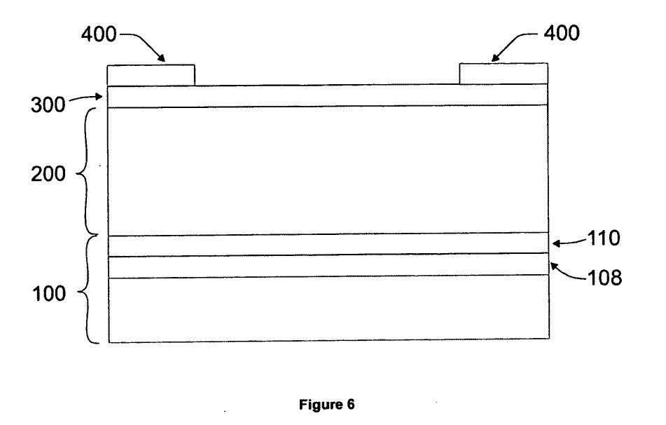

In one embodiment of the invention a quantum well structure, such as one of those shown in FIG. 3, is provided with a top electrode 400, as shown in FIG. 6 in cross-section. Electrode 400 may be a Schottky junction or an n-doped semiconductor layer, such as poly-silicon doped with donor atoms or an n-doped epitaxial SiGe layer or a metal-insulator junction, or an ohmic contact. The device of FIG. 6 can be fabricated in a plurality of modifications, such as to allow light to enter either through the top, or through the substrate, or from the side in case of a waveguide configuration.

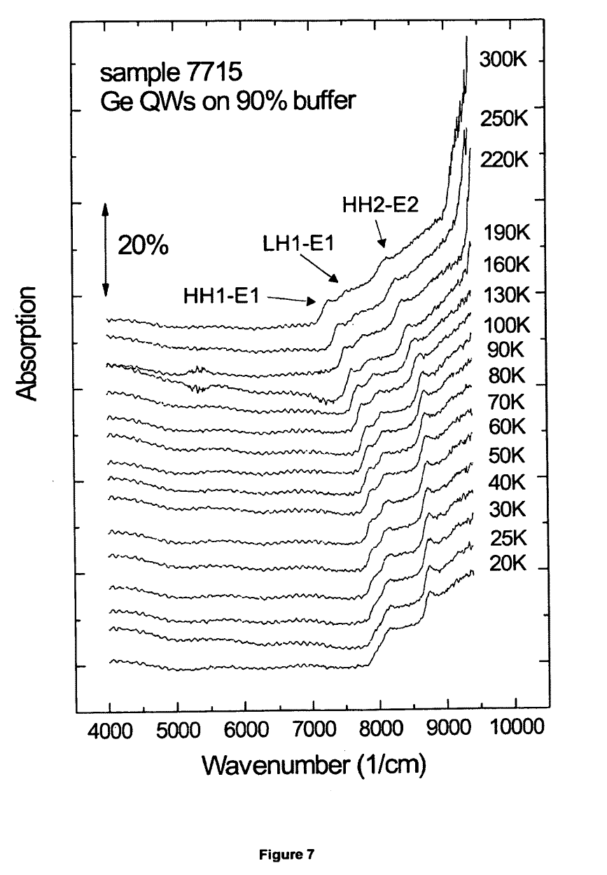

FIG. 7 shows absorption spectra for temperatures between 20 and 300 K, obtained on a MQW structure coherent with a pseudosubstrate 100, graded to a final Ge content x_{f}=0.9. Here, the absorption has been deduced from experimental transmission data through illumination from the top.

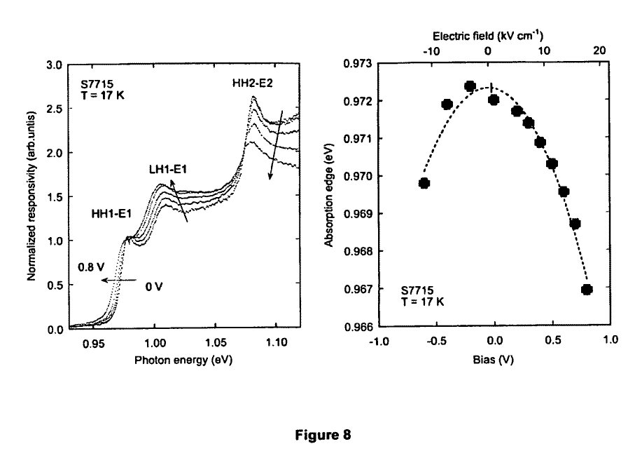

The corresponding absorption spectra, obtained on a device fabricated according to one of the embodiments of FIG. 6, with a Schottky barrier contact 400 on top of the quantum well structure, can be seen in FIG. 8. Here, the absorption, as obtained from photocurrent spectroscopy at a temperature of 17 K, is depicted on the left hand side for various applied voltages across the device. The shift of the absorption edge, corresponding to the transition from the lowest confined hole state HH1 to the lowest confined electron state E1at the Γ-point, derived from the Γ₂, band in FIG. 1, is shown on the right hand side of FIG. 8 as a function of electric field. The shift of the absorption edge can be seen to be quadratic in the electric field.

In another embodiment of the invention the QW structure of FIG. 2 is illuminated by an external light source, such as a solid state laser, providing photons which are absorbed by the QW. Band filling by electron-hole pairs generated by this source may lead to phase space filling or quenching of the excitons, thereby leading to a modulation of the optical absorption. In this embodiment electrical contacts may not be needed. An electric field applied across the device may, however, help in extracting minority carriers, and thus making the device faster.

In another embodiment of the invention the QW structure of FIG. 2 is illuminated by an external light source, such as a solid state laser, providing photons which are not absorbed by the QW. Here, the electric field present in the light source replaces the field applied by the contacts in FIG. 6, leading to a modulation of the absorption through the optical Stark effect.

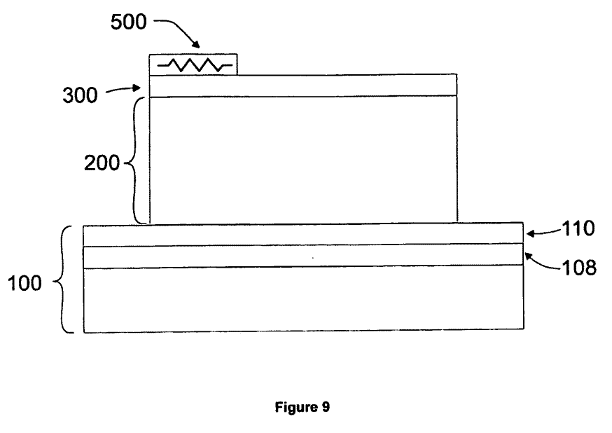

In yet another embodiment of the invention the top contact 400 of FIG. 6 is replaced by a heater element 500 as shown in FIG. 9. In this embodiment the poor heat conduction of SiGe alloys is used to modulate the temperature of the QW structure 200. For this reason, a thick buffer layer is preferably used as the pseudosubstrate 100. A heater element integrated on the QW structure allows for fast modulation of its band structure, thereby giving rise to a modulation of the direct optical transition energies at the Γ-point.

1-11. (canceled)

12. A semiconductor quantum well structure, comprising:
a relaxed Si_{1-x′}Ge_{x′} pseudosubstrate;
at least one well layer above said pseudosubstrate, said at least one well layer having a composition Si₁₋ₓGeₓ, wherein x is chosen such that a Γ_{2′} conduction band minimum lies below a Γ₁₅ state;
barrier layers with a composition Si_{1-y}Ge_{y} and Si_{1-y′}Ge_{y′}, where y<x and y′<x; and
a cap layer having a composition Si_{1-x′}Ge_{x′};
wherein x′ lies in a range of an average Ge content, as calculated from a Ge content in said pseudosubstrate, said at least one well layer, said barrier layers, and said cap layer.

13. The structure according to claim 12, wherein layer compositions and layer thicknesses are chosen to define optical transitions from heavy hole states to electron states at the Γ-point to occur at wavelengths close to 1.3 nm or 1.55 nm.

14. The structure according to claim 12, wherein said pseudosubstrate comprises:
a graded alloy buffer layer with a final Ge content x_{f};
a constant composition buffer layer with Ge content x_{f};
a boron-doped layer with Ge content x_{f}; and
an undoped spacer layer with Ge content x_{f}.

15. The structure according to claim 14, wherein said boron-doped layer and said undoped spacer layer are grown at a lower plasma density and a lower substrate temperature than said buffer layer, and wherein a flux of hydrogen is added to a gas phase, and the flux of hydrogen is higher than a flux of dopant gas.

16. The structure according to claim 12, wherein said pseudosubstrate comprises:
an alloy buffer layer with a constant Ge content x′;
a boron doped layer with a Ge content x′; and
an undoped spacer layer with a Ge content x′.

17. The structure according to claim 16, wherein said boron-doped layer and said undoped spacer layer are grown at a lower plasma density and a lower substrate temperature than said buffer layer, and wherein a flux of hydrogen is added to a gas phase.

18. The structure according to claim 17, wherein the flux of hydrogen is higher than a flux of dopant gas.

19. The structure according to claim 12, wherein a Ge concentration profile within an active layer structure has a shape selected from the following group of shapes:
parabolic in a region of wells;
sinusoidal in well and barrier; and
regions, symmetric or asymmetric step-function.

20. The structure according to claim 12, which further comprises a top electrical contact in any of a plurality of forms selected from the group consisting of:
a Schottky contact;
an n-doped epitaxial-Si or poly-Si layer;
an n-doped epitaxial Si₁₋ₓGeₓ layer, whereby a Ge content x is chosen to be near or equal to a Ge content of said pseudosubstrate;
a metal-insulator layer; and
an ohmic contact.

21. The structure according to claim 12, wherein the layers forming said pseudosubstrate, said at least one well layer, said barrier layers, and said cap layer, are epitaxial layers deposited by low-energy plasma-enhanced chemical vapor deposition (LEPECVD).

22. An opto-electronic device, comprising a structure according to claim 12 formed with a buried contact layer and a top electrode disposed to allow an electric potential to be applied between said buried contact layer and said top electrode to establish an electric field in an active region therebetween, wherein an optical response of the device may be altered by changing the electric field.

23. A device, comprising the quantum well structure according to claim 12 and an external light source supplying photons to be absorbed by the quantum well structure for altering an optical response of the device.

24. A device, comprising the quantum well structure according to claim 12 and an external light source providing photons which are not absorbed by the quantum well structure for altering an optical response of the device.

25. A device, comprising the quantum well structure according to claim 12, wherein a heater integrated with said quantum well structure is used to alter an optical response of the device.
